(19) United States
(12) Patent Application Publication
(10) Pub. No.: US 2021/0232725 A1
(43) Pub. Date: Jul. 29, 2021

(54) SYSTEM AND METHOD FOR TESTING AN INTEGRATED MONITORING SYSTEM

(71) Applicants: ELECTRIC POWER SCIENCE & RESEARCH INSTITUTE OF STATE GRID TIANJN ELECTRIC POWER COMPANY, Tianjin (CN); STATE GRID TIANJIN ELECTRIC POWER COMPANY, Tianjin (CN); STATE GRID CORPORATION OF CHINA, Beijing (CN); FIVE-C SMART POWER GRID TECHNOLOGY CO., LTD., Jiangsu (CN)

(72) Inventors: Pan ZHANG, Tianjin (CN); Zhijun ZHANG, Tianjin (CN); Yanxin SHI, Tianjin (CN); Ning KANG, Tianjin (CN); Xudong WANG, Tianjin (CN); Qiang WANG, Tianjin (CN); Ling JIANG, Tianjin (CN); Jian CHEN, Tianjin (CN); Zi WANG, Tianjin (CN); Minjie MA, Jiangsu (CN); Peng LI, Jiangsu (CN)

(21) Appl. No.: 16/301,536

(22) PCT Filed: Oct. 22, 2018
(86) PCT No.: PCT/CN2018/111158

§ 371 Date: Nov. 14, 2018

(30) Foreign Application Priority Data
Dec. 30, 2017 (CN) 201711491986.7

(51) Int. Cl. G06F 30/20; H04L 12/24

(52) U.S. Cl. CPC G06F 30/20; H04L 41/145

(57) ABSTRACT

Provided are a closed-loop system and a method for testing an intelligent alarm application of an integrated monitoring system. The system includes: a host computer and a slave computer, where the host computer and the slave computer perform downloading files and command interactions through an internal protocol, the host computer includes a visual signal configuration module, a scheduling protocol analysis and simulation module and an evaluation module, and the slave computer includes an intelligent electronic devices (IEDs) server simulation module.

The present application claims the priority of Chinese patent application No. 201711491986.7 filed on Dec. 30, 2017, which is incorporated in the present application by reference in its entirety.

### TECHNICAL FIELD

The present application belongs to the field of power system automation technologies, for example, relates to a system and method for testing an integrated monitoring system.

### BACKGROUND

At present, the construction of smart grid is already in a critical period of the comprehensive construction stage. Then it is especially important and urgent to study an application function architecture and standardized configuration technology of a substation monitoring system adapting to unattended operation and maintenance mode, to achieve an integrated operation control and fine operation management of an intelligent scheduling system and the intelligent substation system, and to comprehensively improve the ability of the intelligent alarm advanced application to process alarm information.

On Feb. 11, 2015, at the regulation work meeting of the State Grid Corporation in 2015, work requirements for automation devices in the substation were proposed: a unified appearance interface, a unified information model, a unified communication service, unified monitoring graphics, standardized parameter configuration, a standardized application function, a standardized version management and a standardized quality control.

In 2016, under the organization of the control center of the State Grid Corporation, domestic mainstream automation device manufacturers actively participated in and carried out the upgrade and development of the monitoring system application function, while how to scientifically and objectively compare and judge the achievement level of the intelligent application function of the integrated monitoring system in the substation of different manufacturers, mature technology and auxiliary tools are in shortage.

At present, alarm information is still displayed in a simple text listing and by classification by the mainstream monitoring system at home and abroad. As the alarm information refreshes quickly, the work to monitor and process each piece of information is still very intensive. Data is still unprocessed for the monitoring personnel, conventional and passive manual post-event monitoring is still relied on, and an intelligent technology support such as an event pre judgment is in shortage. Most of the current optimization methods are mostly in the research stage, and not many practical systems exist. The expert knowledge base of the monitoring system is still in a simple matching stage, the ability of alarm information compression, comprehensive analysis and the like is still weak, and the degree of intelligence is not high. Moreover, although the current integrated monitoring system also uses some methods and means of intelligent alarming, the applicability is not high and no unified standard and evaluation system exists, so that the intelligent alarms are just exploratory in practical engineering applications, cannot be truly implemented and promoted, and cannot bring substantial benefits to operation and maintenance of the intelligent station.

### SUMMARY

The present disclosure provides a system and method for testing an integrated monitoring system with reasonable design, high practicability and high intelligence.

The present application provides a system for testing an integrated monitoring system, including: a host computer and a slave computer, where the host computer and the slave computer perform downloading files and command interactions through an internal protocol. The host computer includes a visual signal configuration module, a scheduling protocol simulation and analysis module and an evaluation module. The slave computer includes an intelligent electronic devices (IEDs) server simulation module. The visual signal configuration module is configured to complete parsing an intelligent substation configuration description (SCD) file, and select alarm signals to complete editing of a sequence and state quantity of the alarm signals, and then configure the alarm signals to form an instantiated alarm signal sequence file; and download a configured intelligent electronic device description (CID) file formed by the instantiated alarm signal sequence file and the parsed SCD file, to the IEDs server simulation module. The IEDs server simulation module is configured to receive the instantiated alarm signal sequence file configured and formed by the visual signal configuration module and the CID file formed by parsing the SCD file, and output signals in the IEDs sequentially to the integrated monitoring system according to an alarm signal content of the instantiated alarm signal sequence file. The scheduling protocol simulation and analysis module is configured to collect an intelligent alarm briefing submitted by the integrated monitoring system. The evaluation module is configured to compare and analyze a content of the collected intelligent alarm briefing of the integrated monitoring system and the alarm signal sequence file configured by the signal configuration module, and output an intelligent alarm function test evaluation result of the integrated monitoring system.

In an embodiment, the scheduling protocol simulation and analysis module is configured to collect the intelligent alarm briefing submitted by the integrated monitoring system through a protocol DLT476 or IEC104.

The present application further provides a method for testing a system for testing an integrated monitoring system. The system for testing the integrated monitoring system includes: a host computer and a slave computer, where the host computer and the slave computer perform downloading files and command interactions through an internal protocol. The host computer includes a visual signal configuration module, a scheduling protocol analysis and simulation module and an evaluation module. The slave computer includes an intelligent electronic devices (IEDs) server simulation module. The test method includes: completing, by the visual signal configuration module, editing an alarm signal sequence template, parsing a substation configuration description (SCD) file to obtain a configured intelligent electronic device description (CID) file and all signals in the SCD file, instantiating the alarm signal sequence template and the all signals in the SCD file to output an instantiated alarm signal sequence file, and associating the instantiated alarm signal sequence file with a main wiring diagram of an intelligent substation to form a visual test; and downloading the instantiated alarm signal sequence file and the CID file formed by parsing the SCD file to the IEDs server simulation module; performing, by the IEDs server simulation module, manufacturing message specification (MMS) initialization on the downloaded CID file, and outputting signals in the IEDs sequentially to the integrated monitoring system according to alarm signal content of the instantiated alarm signal sequence file; generating, by the integrated monitoring system, an intelligent alarm briefing according to alarm signals injected in time sequence by a plurality of instantiated alarm signal sequence files after time in the plurality of instantiated alarm signal sequence files is unified in a unified time coordinate system; receiving, by the scheduling protocol simulation and analysis module, alarm briefing information generated by the integrated monitoring system; and comparing and analyzing, by the evaluation module, the intelligent alarm briefing information received by the scheduling protocol simulation and analysis module and the instantiated alarm signal sequence file in the visual signal configuration module, and outputting an intelligent alarm function test evaluation result of the integrated monitoring system.

In an embodiment, the completing, by the visual signal configuration module, editing the alarm signal sequence template, parsing the SCD file to obtain the CID file and all signals in the SCD file, instantiating the alarm signal sequence template and the all signals in the SCD file to output an instantiated alarm signal sequence file, and associating the instantiated alarm signal sequence file with a main wiring diagram of an intelligent substation to form a visual test; and downloading the instantiated alarm signal sequence file and the CID file formed by parsing the SCD file to the IEDs server simulation module, includes:

editing, by the visual signal configuration module, the signal sequence template in a template editing sub-module according to a judging logic of the intelligent alarm, and storing the signal sequence template in a description keyword manner; importing the SCD file into a SCD parsing sub-module, splitting the CID file, and extracting all signals in the SCD file; matching the signal sequence template and the all signals in the SCD file through the description keyword to form an alarm signal sequence instance, and starting a test; and performing a visual drawing according to the main wiring diagram of the intelligent substation, and associating the alarm signal sequence instance with the main wiring diagram to form a visual test.

In an embodiment, the performing, by the IEDs server simulation module, manufacturing message specification (MMS) initialization on the downloaded CID file, and outputting the signals in the IEDs sequentially to the integrated monitoring system according to the alarm signal content of the instantiated alarm signal sequence file includes:

receiving, by the IEDs server simulation module, a downloaded CID file; parsing, by the IEDs server simulation module, the CID file, and performing MMS server initialization; receiving, by the IEDs server simulation module, at least one downloaded signal sequence instance file; performing, by the IEDs server simulation module, a time coordinate system unification of time described in the plurality of instantiated alarm signal sequence files; and performing, by the IEDs server simulation module, an analog transmission of the alarm signals in an order of the alarm signals in the plurality of instantiated alarm signal sequence files after time in the plurality of instantiated alarm signal sequence files is unified in a unified time coordinate system.

In an embodiment, the comparing and analyzing, by the evaluation module, the received intelligent alarm briefing information and the instantiated alarm signal sequence file, and outputting the intelligent alarm function test evaluation result of the integrated monitoring system includes:

parsing, by the evaluation module, the intelligent alarm briefing and the alarm signal sequence file; extracting, by the evaluation module, a fault time from the intelligent alarm briefing and a transmission time from the alarm signal sequence file, and comparing the fault time and the transmission time; extracting, by the evaluation module, a device name from the intelligent alarm briefing and an intelligent electronic device (IED) description from the alarm signal sequence file, and comparing the extracted device name and the extracted IED description; extracting, by the evaluation module, first event information from the intelligent alarm briefing and second event information from the alarm signal sequence file, and comparing the first event information and the second event information; extracting, by the evaluation module, a fault reason from the intelligent alarm briefing and a fault type from the alarm signal sequence file, and comparing the fault reason and the fault type; and providing, by the evaluation module, the intelligent alarm function test evaluation result of the integrated monitoring system according to comparison results.

In an embodiment, the receiving, by the scheduling protocol simulation and analysis module, the alarm briefing information generated by the integrated monitoring system includes: collecting, by the scheduling protocol simulation and analysis module, the intelligent alarm briefing submitted by the integrated monitoring system through a protocol DLT476 or IEC104.

The present application provides a system and method for testing an integrated monitoring system, and, for application function modules such as an intelligent alarm, formulates a test and detection process, develops a standardized test and detection system, and performs an operation evaluation based on the detection result.

Based on evaluation requirements of advanced applications of the monitoring system, this application formulates an intelligent alarm evaluation solution, comprehensively judges the functional state of the advanced applications and discovers potential defects from two aspects of the in-station device analog and scheduling. This application may assist the operation and maintenance personnel to timely discover and eliminate safety hazards caused by failure and low timeliness of advanced application functions, reduce the hazard cost of the advanced applications of the substation monitoring system, improve the working efficiency of the advanced applications of the substation monitoring system, and ensure that the alarm information is quickly and well dealt with, to adapt to the future development needs of the intelligent grid monitoring system and to meet the development needs of the substation for energy conservation and emission reduction, clean and environmental protection and economic saving, which have good comprehensive benefits. After the closed-loop test system for the intelligent alarm advanced application of the integrated monitoring system is used and with a unified evaluation standard and evaluation system and the closed-loop manner in the test process, a standardized test on multiple types of intelligent alarm manufacturers may be carried out to unify the expert pool judgment criteria for intelligent alarms, the derivation process of intelligent alarms, the derivation result of intelligent alarms, the format of intelligent alarm briefings, and the transmission modes of intelligent alarm briefings and scheduling, which plays a certain positive role in the promotion and application of intelligent alarms and the practical usage in the intelligent substation.

### BRIEF DESCRIPTION OF DRAWINGS

FIG. 1A is a structural block diagram of a system according to an embodiment;

FIG. 1B is a flowchart of a test method applied in a closed-loop system for testing an intelligent alarm advanced application of an integrated monitoring system according to an embodiment;

FIG. 2 is a processing flowchart of a visual signal configuration module according to an embodiment;

FIG. 3 is a transmission flowchart of an IEDs server simulation module according to an embodiment; and

FIG. 4 is an evaluation flowchart according to an embodiment.

### DETAILED DESCRIPTION

Embodiments of the present disclosure will be described below in detail in conjunction with the drawings.

The present disclosure provides a closed-loop system and method for testing an intelligent alarm advanced application of an integrated monitoring system. With the system, an automatic test of an intelligent alarm manufacturer may be completed, the problem of lack of intelligent alarm function test tools may be effectively solved, and the standardization and utility of intelligent alarm engineering is pushed, which is very beneficial for improving the operation and maintenance level of the intelligent station.

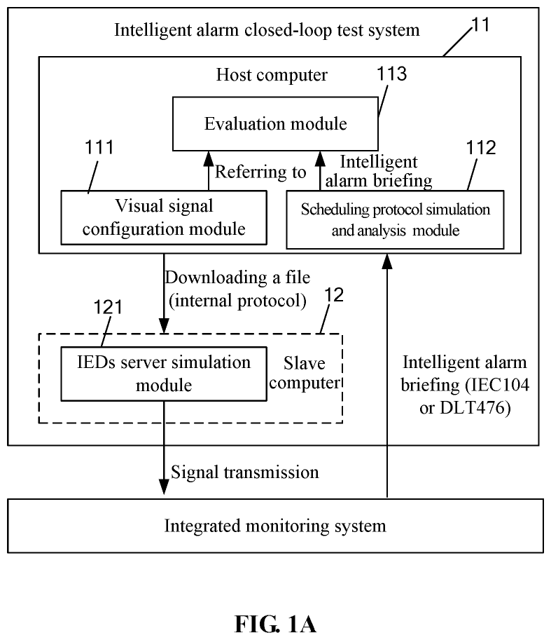

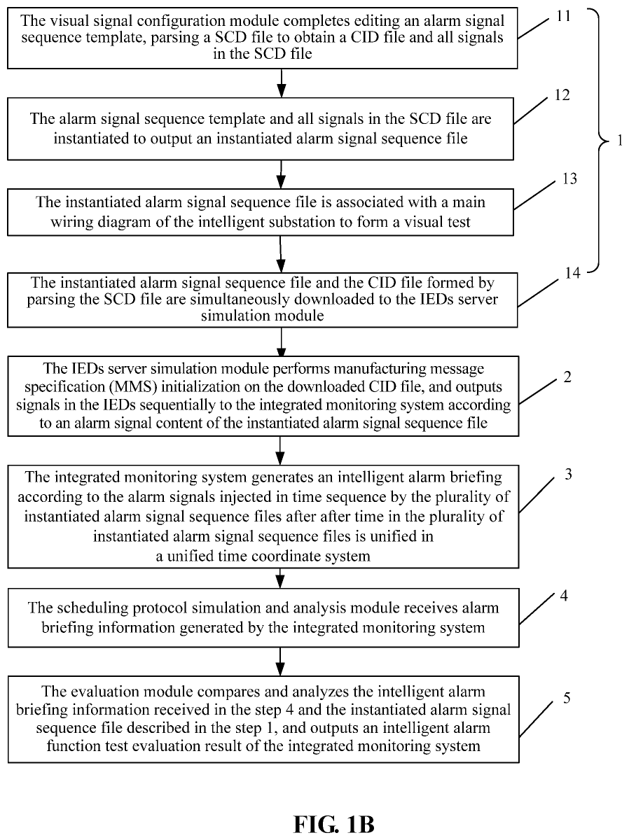

The application provides a closed-loop system for testing an intelligent alarm application of an integrated monitoring system. As shown in FIG. 1A, the system includes: a host computer 11 and a slave computer 12, where the host computer 11 and the slave computer 12 perform downloading files and command interactions through an internal protocol. The host computer 11 includes a visual signal configuration module 111, a scheduling protocol simulation and analysis module 112 and an evaluation module 113. The slave computer 12 includes an IEDs server simulation module 121. The four modules described above work together to form a close-loop test system as shown in FIG. 1A.

The visual signal configuration module 111 is configured to complete parsing an intelligent substation configuration description (SCD) file, and select alarm signals to complete an editing of a sequence and state quantity of the alarm signals, and then configure the alarm signals to form an instantiated alarm signal sequence file; and download the instantiated alarm signal sequence file and a CID file formed by parsing the SCD file, to the IEDs server simulation module.

In an embodiment, the selection order of the alarm signals may refer to relevant provisions in the Criterion Specifications for Comprehensive Analysis of Intelligent Substation Failure (included in Functional Specifications for Integrated Monitoring System of Intelligent Substation, Q/GDW678-2011, China State Grid Corporation Enterprise Standard, 2011).

The IEDs server simulation module 121 is configured to receive the instantiated alarm signal sequence file configured and formed by the signal configuration module and the CID file formed by parsing the SCD file, and output signals in the IEDs sequentially to the integrated monitoring system according to alarm signal content of the instantiated alarm signal sequence file. The signals in the IEDs may be output to the integrated monitoring system described above according to a communication standard IEC61850.

In present embodiment, the integrated monitoring system described above may process the received alarm signal injected in sequence by the alarm signal sequence file to form an intelligent alarm briefing.

The scheduling protocol simulation and analysis module 112 is configured to collect an intelligent alarm briefing submitted by the integrated monitoring system described above. In an embodiment, the scheduling protocol simulation and analysis module 112 is configured to may collect the intelligent alarm briefing submitted by the integrated monitoring system described above through a protocol DLT476 or IEC104. In an embodiment, content of the intelligent alarm briefing is shown as follows:

<! System (System)=Lanxi Substation Version=V1.0 Encoding=UTF-8 Type=Full Model Time=‘20111104_15:02:26_120’!>

<E>
<class name entity (Entity)=‘Lanxi’>

| @# | Num | Property name | Value |
|---|---|---|---|
| # | 1 | Time | ‘2011-11-04 15:02:26:120’ |
| # | 2 | Device name | Zhejiang. Lanxi/220 kV. |
| | | | East brand line 2337.ARP301 |
| # | 3 | Event | Trip |
| # | 4 | Reason | Ground fault |

</Class name::Lanxi>

</E>.

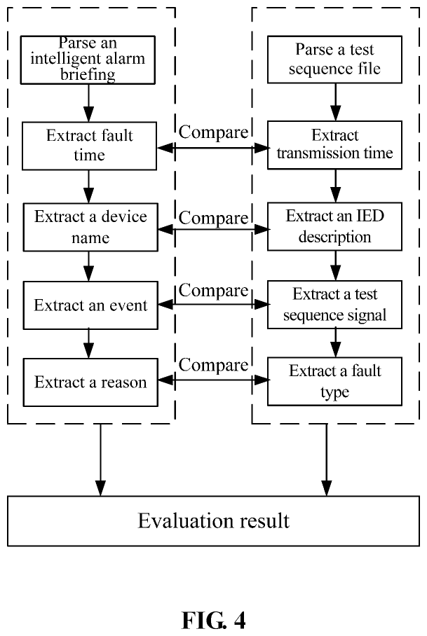

The evaluation module 113 is configured to compare and analyze a content of the collected intelligent alarm briefing of the integrated monitoring system described above and the alarm signal sequence file configured by the signal configuration module, and output an intelligent alarm function test evaluation result of the integrated monitoring system described above. The evaluation result may be content shown in FIG. 4.

The application further provides a closed-loop method for testing an intelligent alarm application of an integrated monitoring system. As shown in FIG. 1B, the test system includes: a host computer and a slave computer, where the host computer and the slave computer perform downloading files and command interactions through an internal protocol. The host computer includes a visual signal configuration module, a scheduling protocol analysis and simulation module and an evaluation module, and the slave computer includes an intelligent electronic devices (IEDs) server simulation module. The test method includes steps 1 to 5 described below.

A step 1 includes a step 11 in which the visual signal configuration module completes editing an alarm signal sequence template, parsing a SCD file to obtain a CID file and all signals in the SCD file. The step 1 includes a step 12 in which the alarm signal sequence template described above and the CID file described above are instantiated to output an instantiated alarm signal sequence file. The step 1 includes a step 13 in which the instantiated alarm signal sequence file is associated with a main wiring diagram of the intelligent substation described above to form a visual test. The step 1 includes a step 14 in which the instantiated alarm signal sequence file and the CID file formed by parsing the SCD file are downloaded to the IEDs server simulation module.

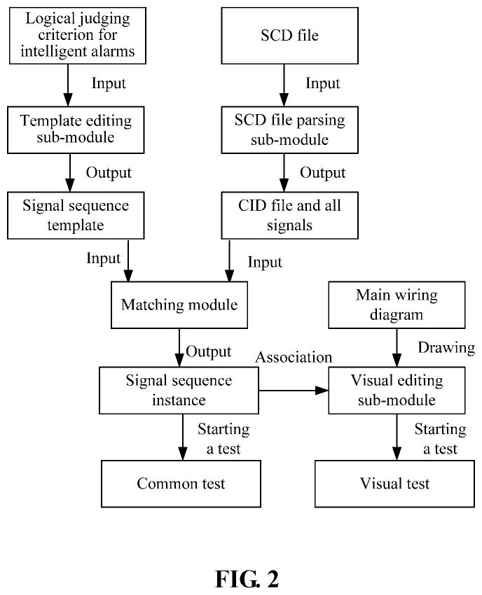

As shown in FIG. 2, the step 1 may include the steps described below.

(1) The visual signal configuration module is configured to edit the signal sequence template in a template editing sub-module according to a judging logic of the intelligent alarm, and stores the signal sequence template in a description keyword manner.

(2) The SCD file is imported into a SCD parsing sub-module, the CID file is split, and all signals in the SCD file are extracted.

(3) The signal sequence template and the all signals in the SCD file are matched through the description keyword to form an alarm signal sequence instance, and a test is started.

(4) A visual drawing is performed according to the main wiring diagram of the intelligent substation described above, and the alarm signal sequence instance described in a step (3) is associated with the main wiring diagram to form a visual test.

In a step 2, the IEDs server simulation module performs manufacturing message specification (MMS) initialization on the downloaded CID file, and outputs signals in the IEDs sequentially to the integrated monitoring system described above according to alarm signal content of the instantiated alarm signal sequence file.

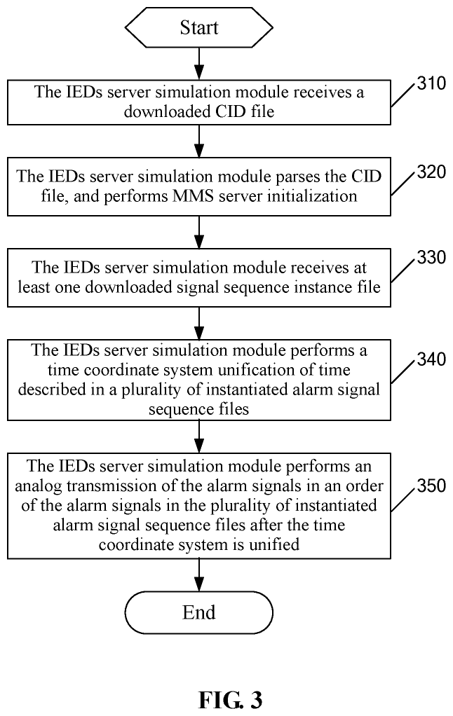

As shown in FIG. 3, the step 2 may include the steps described below.

In a step 310, the IEDs server simulation module receives the downloaded CID file.

In a step 320, the IEDs server simulation module parses the CID file, and performs MMS server initialization.

In a step 330, the IEDs server simulation module receives at least one downloaded signal sequence instance file.

In a step 340, the IEDs server simulation module performs a time coordinate system unification of time described in the plurality of instantiated alarm signal sequence files.

In a step 350, the IEDs server simulation module performs an analog transmission of the alarm signals in an order of the alarm signals in the plurality of instantiated alarm signal sequence files after the time coordinate system is unified.

In a step 3, the integrated monitoring system generates an intelligent alarm briefing according to the alarm signals injected in time sequence by the plurality of instantiated alarm signal sequence files after the time coordinate system is unified. In an embodiment, the intelligent alarm briefing may be in a format based on the Functional Specifications for Integrated Monitoring System of Intelligent Substation, (Q/GDW678-2011, China State Grid Corporation Enterprise Standard, 2011).

In a step 4, the scheduling protocol simulation and analysis module receives alarm briefing information generated by the integrated monitoring system.

In an embodiment, the step in which the scheduling protocol simulation and analysis module receives the intelligent alarm briefing information generated by the integrated monitoring system includes that the scheduling protocol simulation and analysis module may receive the intelligent alarm briefing submitted by the integrated monitoring system described above through a protocol DLT476 or IEC104.

In a step 5, the evaluation module compares and analyzes the intelligent alarm briefing information received in the step 4 and the instantiated alarm signal sequence file described in the step 1, and outputs an intelligent alarm function test evaluation result of the integrated monitoring system.

As shown in FIG. 4, the step 5 may include the steps described below.

(1) The evaluation module parses the intelligent alarm briefing and the alarm signal sequence file.

(2) The evaluation module extracts a fault time from the intelligent alarm briefing and a transmission time from the alarm signal sequence file, and compares the fault time and the transmission time.

(3) The evaluation module extracts a device name from the intelligent alarm briefing and an IED description from the alarm signal sequence file, and compares the extracted device name and IED description.

(4) The evaluation module extracts first event information from the intelligent alarm briefing and second event information from the alarm signal sequence file, and compares the first event information and the second event information.

(5) The evaluation module extracts a fault reason from the intelligent alarm briefing and a fault type from the alarm signal sequence file, and compares the fault reason and the fault type.

(6) The evaluation module provides an intelligent alarm function test evaluation result of the integrated monitoring system according to comparison results.

1. A system for testing an integrated monitoring system, comprising: a host computer and a slave computer, wherein the host computer and the slave computer perform downloading files and command interactions through an internal protocol, wherein the host computer comprises a visual signal configuration module, a scheduling protocol simulation and analysis module and an evaluation module, and the slave computer comprises an intelligent electronic devices (IEDs) server simulation module;
wherein the visual signal configuration module is configured to complete parsing an intelligent substation configuration description (SCD) file, and select alarm signals to complete editing of a sequence and state quantity of the alarm signals, and then configure the alarm signals to form an instantiated alarm signal sequence file; and download the instantiated alarm signal sequence file and a configured intelligent electronic device description (CID) file formed by parsing the SCD file, to the IEDs server simulation module;
wherein the IEDs server simulation module is configured to receive the instantiated alarm signal sequence file configured and formed by the visual signal configuration module and the CID file formed by parsing the SCD file, and output signals in the IEDs sequentially to the integrated monitoring system according to an alarm signal content of the instantiated alarm signal sequence file;
wherein the scheduling protocol simulation and analysis module is configured to collect an intelligent alarm briefing submitted by the integrated monitoring system; and
wherein the evaluation module is configured to compare and analyze a content of the collected intelligent alarm briefing of the integrated monitoring system and the alarm signal sequence file configured by the signal configuration module, and output an intelligent alarm function test evaluation result of the integrated monitoring system.

2. The test system of claim 1, wherein the scheduling protocol simulation and analysis module is configured to collect the intelligent alarm briefing submitted by the integrated monitoring system through a protocol DLT476 or IEC104.

3. A method for testing an integrated monitoring system, applied to a system for testing the integrated monitoring system, wherein the system for testing the integrated monitoring system comprises: a host computer and a slave computer, wherein the host computer and the slave computer perform downloading files and command interactions through an internal protocol, wherein the host computer comprises a visual signal configuration module, a scheduling protocol simulation and analysis module and an evaluation module, and the slave computer comprises an intelligent electronic devices (IEDs) server simulation module;
the method comprises:
completing, by the visual signal configuration module, editing an alarm signal sequence template, parsing a substation configuration description (SCD) file to obtain a configured intelligent electronic device description (CID) file and all signals in the SCD file, instantiating the alarm signal sequence template and the all signals in the SCD file to output an instantiated alarm signal sequence file, and associating the instantiated alarm signal sequence file with a main wiring diagram of an intelligent substation to form a visual test; and downloading the instantiated alarm signal sequence file and the CID file formed by parsing the SCD file to the IEDs server simulation module;
performing, by the IEDs server simulation module, manufacturing message specification (MMS) initialization on the downloaded CID file, and outputting signals in the IEDs sequentially to the integrated monitoring system according to alarm signal contents of the instantiated alarm signal sequence file;
generating, by the integrated monitoring system, an intelligent alarm briefing according to alarm signals injected in time sequence by a plurality of instantiated alarm signal sequence files after time in the plurality of instantiated alarm signal sequence files is unified in a unified time coordinate system;
receiving, by the scheduling protocol simulation and analysis module, alarm briefing information generated by the integrated monitoring system; and
comparing and analyzing, by the evaluation module, the intelligent alarm briefing information received by the scheduling protocol simulation and analysis module and the instantiated alarm signal sequence file in the visual signal configuration module, and outputting an intelligent alarm function test evaluation result of the integrated monitoring system.

4. The test method of claim 3, wherein the completing, by the visual signal configuration module, editing the alarm signal sequence template, parsing the SCD file to obtain the CID file and the all signals in the SCD file, instantiating the alarm signal sequence template and the all signals in the SCD file to output the instantiated alarm signal sequence file, and associating the instantiated alarm signal sequence file with the main wiring diagram of the intelligent substation to form the visual test; and downloading the instantiated alarm signal sequence file and the CID file formed by parsing the SCD file to the IEDs server simulation module, comprises:
editing, by the visual signal configuration module, the alarm signal sequence template in a template editing sub-module according to a judging logic of the intelligent alarm, and storing the alarm signal sequence template in a description keyword manner;
importing the SCD file into a SCD parsing sub-module, splitting the CID file, and extracting the all signals in the SCD file;
matching the alarm signal sequence template and the all signals in the SCD file through the description keyword to form an alarm signal sequence instance, and starting a test; and
performing a visual drawing according to the main wiring diagram of the intelligent substation, and associating the alarm signal sequence instance with the main wiring diagram to form a visual test.

5. The method of claim 3 , wherein the performing, by the IEDs server simulation module, the manufacturing message specification (MMS) initialization on the downloaded CID file, and outputting the signals in the IEDs sequentially to the integrated monitoring system according to the alarm signal content of the instantiated alarm signal sequence file, comprises:
receiving a downloaded CID file by the IEDs server simulation module;
parsing, by the IEDs server simulation module, the CID file, and performing MMS server initialization;
receiving at least one downloaded signal sequence instance file by the IEDs server simulation module;
unifying, by the IEDs server simulation module, time described in the plurality of instantiated alarm signal sequence files in the unified time coordinate system ; and
performing, by the IEDs server simulation module, an analog transmission of the alarm signals in an order of the alarm signals in the plurality of instantiated alarm signal sequence files after time in the plurality of instantiated alarm signal sequence files is unified in the unified time coordinate system.

6. The method of claim 3, wherein the comparing and analyzing, by the evaluation module, the received intelligent alarm briefing information and the instantiated alarm signal sequence file, and outputting the intelligent alarm function test evaluation result of the integrated monitoring system comprises:
parsing, by the evaluation module, the intelligent alarm briefing and the alarm signal sequence file;
extracting, by the evaluation module, fault time from the intelligent alarm briefing and transmission time from the alarm signal sequence file, and comparing the fault time and the transmission time;
extracting, by the evaluation module, a device name from the intelligent alarm briefing and an intelligent electronic device (IED) description from the alarm signal sequence file, and comparing the extracted device name and the extracted IED description;
extracting, by the evaluation module, first event information from the intelligent alarm briefing and second event information from the alarm signal sequence file, and comparing the first event information and the second event information;
extracting, by the evaluation module, a fault reason from the intelligent alarm briefing and a fault type from the alarm signal sequence file, and comparing the fault reason and the fault type; and
providing, by the evaluation module, the intelligent alarm function test evaluation result of the integrated monitoring system according to above comparison results.

7. The method of claim 3, wherein the receiving, by the scheduling protocol simulation and analysis module, the alarm briefing information generated by the integrated monitoring system comprises:
collecting, by the scheduling protocol simulation and analysis module, the intelligent alarm briefing submitted by the integrated monitoring system through a protocol DLT476 or IEC104.

8. The method of claim 4, wherein the performing, by the IEDs server simulation module, the manufacturing message specification (MMS) initialization on the downloaded CID file, and outputting the signals in the IEDs sequentially to the integrated monitoring system according to the alarm signal content of the instantiated alarm signal sequence file, comprises:
receiving a downloaded CID file by the IEDs server simulation module;
parsing, by the IEDs server simulation module, the CID file, and performing MMS server initialization;
receiving at least one downloaded signal sequence instance file by the IEDs server simulation module;
unifying, by the IEDs server simulation module, time described in the plurality of instantiated alarm signal sequence files in the unified time coordinate system ; and
performing, by the IEDs server simulation module, an analog transmission of the alarm signals in an order of the alarm signals in the plurality of instantiated alarm signal sequence files after time in the plurality of instantiated alarm signal sequence files is unified in the unified time coordinate system.

9. The method of claim 4, wherein the comparing and analyzing, by the evaluation module, the received intelligent alarm briefing information and the instantiated alarm signal sequence file, and outputting the intelligent alarm function test evaluation result of the integrated monitoring system comprises:
parsing, by the evaluation module, the intelligent alarm briefing and the alarm signal sequence file;
extracting, by the evaluation module, fault time from the intelligent alarm briefing and transmission time from the alarm signal sequence file, and comparing the fault time and the transmission time;
extracting, by the evaluation module, a device name from the intelligent alarm briefing and an intelligent electronic device (IED) description from the alarm signal sequence file, and comparing the extracted device name and the extracted IED description;
extracting, by the evaluation module, first event information from the intelligent alarm briefing and second event information from the alarm signal sequence file, and comparing the first event information and the second event information;
extracting, by the evaluation module, a fault reason from the intelligent alarm briefing and a fault type from the alarm signal sequence file, and comparing the fault reason and the fault type; and
providing, by the evaluation module, the intelligent alarm function test evaluation result of the integrated monitoring system according to above comparison results.
